(19) United States
(12) Patent Application Publication
(10) Pub. No.: US 2025/0279304 A1
(43) Pub. Date: Sep. 4, 2025

(54) Semiconductor Manufacturing Apparatus, Pushup Unit, and Method for Manufacturing Semiconductor Device

(71) Applicant: Fasford Technology Co., Ltd., Minami-Alps City (JP)

(72) Inventors: Yuki NAKUI, Minami Alps (JP); Akira SAITO, Minami-Alps (JP); Naoki OKAMOTO, Minami-Alps (JP)

(21) Appl. No.: 19/052,499

(22) Filed: Feb. 13, 2025

(30) Foreign Application Priority Data
Mar. 4, 2024 (JP) 2024-032076

(51) Int. Cl. H01L 21/677; H01L 21/683

(52) U.S. Cl. CPC H01L 21/67712; H01L 21/6773; H01L 21/6836

(57) ABSTRACT

To provide a new mechanism for driving a plurality of blocks of a pushup unit. A pushup unit includes a mechanism section for independently moving each of a plurality of blocks up and down. The mechanism section includes a first mechanism section having: (a) a first member having an upper surface, a lower surface opposite the upper surface, and a through-hole penetrating between the upper surface and the lower surface; (b) a first rod connected to the upper surface of the first member to convey the vertical motion of the first member to the blocks; and (c) a second rod extended from below through the through-hole to convey the vertical motion to the blocks.

### CLAIM OF PRIORITY

The present application claims priority from Japanese patent application JP 2024-032076 filed on Mar. 4, 2024, the content of which is hereby incorporated by reference into this application.

### BACKGROUND OF THE INVENTION

The present disclosure relates to a semiconductor manufacturing apparatus, and is applicable, for example, to a die bonder having a pushup unit.

One step in a semiconductor device manufacturing process is a peeling step in which a die separated from a wafer is peeled off from a dicing tape. In the peeling step, for example, the die is pushed up from the back surface of the dicing tape by a pushup unit, then peeled off one by one from the dicing tape held by a wafer supply unit, and picked up by using a suction nozzle such as a collet disposed on a pickup head or a bond head.

For example, the pushup unit removes the dicing tape from the periphery of the die by moving a plurality of blocks up and down. A drive section including a motor and a plunger mechanism may be provided for each block (refer, for example, to Japanese Unexamined Patent Application Publication No. 2017-224640).

### SUMMARY OF THE INVENTION

An object of the present disclosure is to provide a new mechanism for driving a plurality of blocks of a pushup unit. Other objects and novel features will be apparent from the description of this document and the accompanying drawings.

A brief summary of representative aspects of the present disclosure is given below.

In short, the pushup unit includes a mechanism section for independently moving each of a plurality of blocks up and down. The mechanism section includes a first mechanism section having: (a) a first member having an upper surface, a lower surface opposite the upper surface, and a through-hole penetrating between the upper surface and the lower surface; (b) a first rod connected to the upper surface of the first member to convey the vertical motion of the first member to the blocks; and (c) a second rod extended from below through the through-hole to convey the vertical motion to the blocks.

The present disclosure makes it possible, for example, to increase the number of pushup blocks.

### BRIEF DESCRIPTION OF THE DRAWINGS

FIG. 1 is a schematic top view illustrating an example of the configuration of a die bonder according to an embodiment.

FIG. 2 is a diagram illustrating a schematic configuration as viewed in the direction of arrow A in FIG. 1.

FIG. 3 is a schematic cross-sectional view illustrating essential parts of a wafer supply unit depicted in FIG. 1.

FIG. 4 is a block diagram illustrating a schematic configuration of a control system of the die bonder depicted in FIG. 1.

FIG. 5 is a flowchart illustrating a method for manufacturing semiconductor device by using the die bonder depicted in FIG. 1.

FIG. 6 is a front view of a pushup unit in the embodiment.

FIG. 7 is a schematic diagram illustrating the pushup unit depicted in FIG. 6.

FIG. 8 is a top view of a head section depicted in FIG. 6.

FIG. 9 is a longitudinal cross-sectional view of an upper plate section depicted in FIG. 6.

FIG. 10 is a transverse cross-sectional view of the upper plate section taken along line C-C in FIG. 9.

FIG. 11 is a transverse cross-sectional view of the upper plate section taken along line E-E in FIG. 9.

FIG. 12 is a longitudinal cross-sectional view of a lower block section depicted in FIG. 6.

FIG. 13 is a transverse cross-sectional view of the lower block section taken along line F-F in FIG. 12.

FIG. 14 is a top view illustrating an example of layout of a drive section depicted in FIG. 6.

FIG. 15 is a side view illustrating an example layout of the drive section depicted in FIG. 6.

FIG. 16 is a diagram illustrating an example of the configuration of the drive section depicted in FIG. 15.

FIG. 17 is a diagram illustrating another example of the configuration of the drive section depicted in FIG. 15.

### DETAILED DESCRIPTION OF THE PREFERRED EMBODIMENTS

An embodiment will be described below with reference to the drawings. It should be noted that in the following description, the same components are indicated by the same reference numerals, and the repeated description thereof may be omitted. It should be noted that to make the description more clearly, the drawings may be schematically represented for the widths, thicknesses, shapes, and the like of the respective portions as compared with the actual form. In addition, also between a plurality of mutual drawings, the dimension relationships between the respective elements, the ratios between the respective elements, and the like do not always coincide with each other.

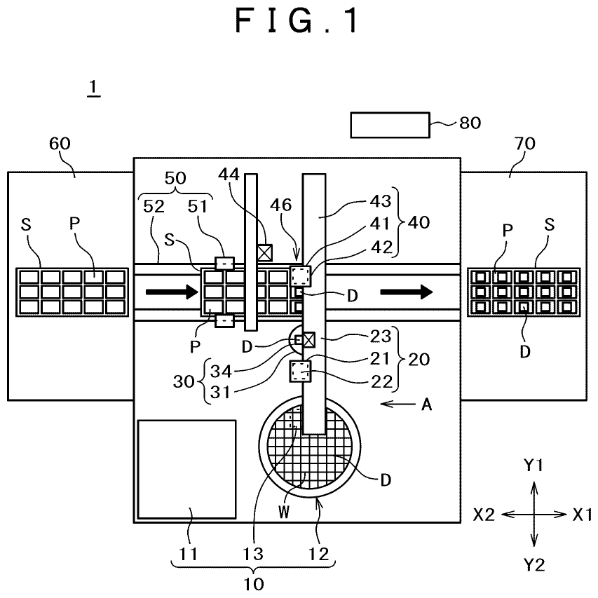

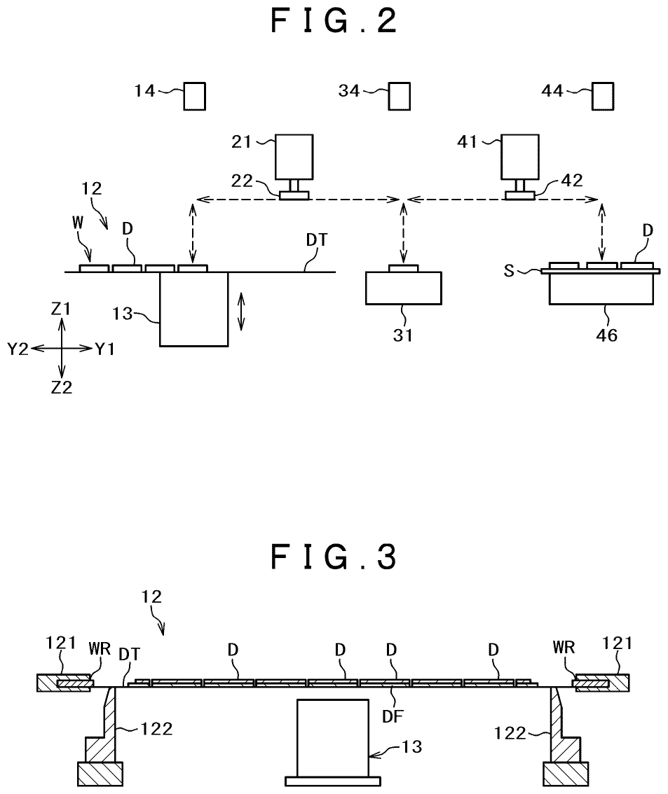

A configuration of a die bonder, which is an embodiment of a semiconductor manufacturing apparatus, will now be described with reference to FIGS. 1 to 3. FIG. 1 is a schematic top view illustrating an example of the configuration of a die bonder according to an embodiment. FIG. 2 is a diagram illustrating a schematic configuration as viewed in the direction of arrow A in FIG. 1. FIG. 3 is a schematic cross-sectional view illustrating essential parts of a wafer supply unit depicted in FIG. 1.

The die bonder 1 broadly includes a wafer supply unit 10, a pickup unit 20, an intermediate stage unit 30, a bonding unit 40, a carrier unit 50, a substrate supply unit 60, a substrate unloading unit 70, and a control unit (controller) 80. The Y2-Y1 direction is the front-back direction of the die bonder 1, the X2-X1 direction is the left-right direction, and the Z1-Z2 direction is the vertical direction. The wafer supply unit 10 is disposed on the front side of the die bonder 1, and the bonding unit 40 is disposed on the back side.

The wafer supply unit 10 includes a wafer cassette lifter 11, a wafer holding table 12, a pushup unit 13, and a wafer recognition camera 14.

The wafer cassette lifter 11 vertically moves a wafer cassette (not depicted) to a wafer transfer height. A plurality of wafer rings WR are stored in the wafer cassette. A wafer correction chute (not depicted) aligns the wafer rings WR supplied from the wafer cassette lifter 11. A wafer extractor (not depicted) removes the wafer rings WR from the wafer cassette, and supplies the wafer rings WR to the wafer holding table 12 or removes the wafer rings WR from the wafer holding table 12 and stores the wafer rings WR in the wafer cassette.

The wafer holding table 12 has an expand ring 121 and a support ring 122. The expand ring 121 holds the wafer rings WR. The support ring 122 horizontally positions a dicing tape DT that is held by the wafer rings WR. The pushup unit 13 is disposed inside the support ring 122.

A wafer W is adhered (attached) to the dicing tape DT, and the wafer W is divided into a plurality of dies D. The dicing tape DT is transparent to visible light. A film-like adhesive material DF called a die attach film (DAF) is attached between the wafer W and the dicing tape DT. The adhesive material DF hardens when heated.

The wafer holding table 12 is moved in the X1-X2 and Y1-Y2 directions by a drive unit (not depicted) in order to move the dies D, which are to be picked up, to the position of the pushup unit 13. Further, the drive unit (not depicted) causes the wafer holding table 12 to rotate the wafer rings WR within the XY plane. The pushup unit 13 is moved in the vertical direction by the drive unit (not depicted). The pushup unit 13 peels off the dies D from the dicing tape DT. The wafer holding table 12 and the pushup unit 13 form a pickup device. The pickup device may include the pickup unit 20.

When the dies D are to be pushed up, the wafer holding table 12 lowers the expand ring 121 that holds the wafer rings WR. In this instance, the support ring 122 does not lower. Therefore, the dicing tape DT held by the wafer rings WR is stretched to increase the spacing between the dies D. This prevents interference and contact between the dies D, and thus makes it easier to separate and push up the individual dies D. The expand ring 121 and the support ring 122 are collectively referred to as an expander. The pushup unit 13 pushes up the dies D from below, thereby promoting the peeling of the dies D and improving the performance of a collet to pick up the dies D.

The wafer recognition camera 14 recognizes a pickup position of the dies D, which are to be picked up from the wafer W, and inspects the surface of the dies D.

The pickup unit 20 has a pickup head 21 and a Y drive unit 23. The pickup head 21 is provided with a collet 22 that adsorbs and holds the peeled dies D at its tip. The pickup head 21 picks up the dies D from the wafer supply unit 10, and places the dies D on an intermediate stage 31. The Y drive unit 23 moves the pickup head 21 in the Y1-Y2 direction. The pickup unit 20 has various drive unit (not depicted) for raising, lowering, or rotating the pickup head 21, or moving the pickup head 21 in the X direction.

The intermediate stage unit 30 has a stage recognition camera 34 and the intermediate stage 31 on which the dies D are placed. The stage recognition camera 34 is used for recognizing the dies D on the intermediate stage 31. The intermediate stage 31 has a suction hole for adsorbing the dies D placed thereon. The placed dies D are temporarily held on the intermediate stage 31. The intermediate stage 31 acts as a placement stage on which the dies D are placed, and also acts as a pickup stage from which the dies D are picked up.

The bonding unit 40 has a bond head 41, a Y drive unit 43, a substrate recognition camera 44, and a bond stage 46. The bond head 41 is provided with a collet 42 that adsorbs and holds the dies D at its tip. The Y drive unit 43 moves the bond head 41 in the Y1-Y2 direction. The substrate recognition camera 44 captures an image of a position recognition mark (not depicted) on a substrate S to recognize a bond position. Here, a plurality of product areas (hereinafter referred to as a package areas P), which will eventually become one package, are formed on the substrate S. The position recognition mark is provided for each of the package areas P. When the dies D are to be placed on the substrate S, the bond stage 46 is raised to support the substrate S from below. The bond stage 46 has a suction port (not depicted) for vacuum adsorption of the substrate S, and is capable of fastening the substrate S. The bond stage 46 has a heating portion (not depicted) for heating the substrate S. The bonding unit 40 has various driving unit (not depicted) for raising, lowering, or rotating the bond head 41 or moving the bond head 41 in the X direction.

With the above-described configuration, the bond head 41 corrects the pickup position and posture in accordance with image data obtained by the stage recognition camera 34, and picks up the dies D from the intermediate stage 31. Then, the bond head 41 performs bonding on the package areas P of the substrate S in accordance with the image data obtained by the substrate recognition camera 44, or performs bonding in stack form on the dies already bonded on the package areas P of the substrate S.

The carrier unit 50 has carrying claws 51 and a carrying lane 52. The carrying claws 51 grip and carry the substrate S. The substrate S moves in the carrying lane 52. The substrate S moves in the X direction when a nut (not depicted) of the carrying claws 51 provided on the carrying lane 52 is driven by a ball screw (not depicted) provided along the carrying lane 52. With the above-described configuration, the substrate S moves from the substrate supply unit 60 along the carrying lane 52 to the bond position, and after bonding, moves to the substrate unloading unit 70 and delivers the substrate S to the substrate unloading unit 70.

The substrate supply unit 60 removes the substrate S, which has been stored in a carrying jig and loaded, from the carrying jig, and supplies the substrate S to the carrier unit 50. The substrate unloading unit 70 receives the substrate S, which has been carried by the carrier unit 50, and stores the substrate S in the carrying jig.

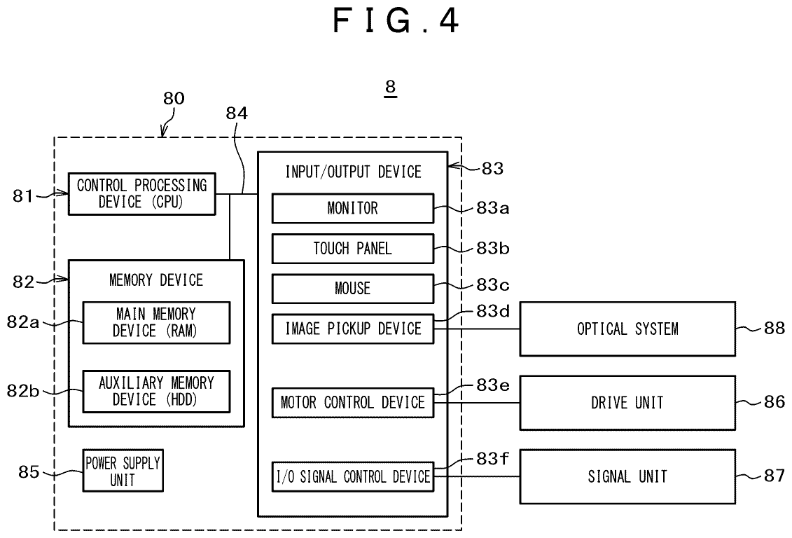

The control unit 80 will now be described with reference to FIG. 4. FIG. 4 is a block diagram illustrating a schematic configuration of a control system of the die bonder depicted in FIG. 1.

The control system 8 includes, for example, the control unit (controller) 80, a drive unit 86, a signal unit 87, and an optical system 88. The control unit 80 broadly includes a control processing device 81, a memory device 82, an input/output device 83, a bus line 84, and a power supply unit 85. The control processing device 81 is mainly formed by a CPU (Central Processing Unit). The memory device 82 includes a main memory device 82a and an auxiliary memory device 82b. The main memory device 82a is formed by a RAM (Random Access Memory) that stores, for example, processing programs. The auxiliary memory device 82b is formed by an HDD (Hard Disk Drive), an SSD (Solid State Drive), or other memory device that stores control data and image data necessary for control.

The input/output device 83 includes a monitor 83a, a touch panel 83b, a mouse 83c, and an image pickup device 83d. The monitor 83a displays information indicating, for example, the status of a device. The touch panel 83b inputs operator instructions. The mouse 83c operates the monitor 83a. The image pickup device 83d acquires image data from the optical system 88. The input/output device 83 further includes a motor control device 83e and an I/O signal control device 83f. The motor control device 83e controls, for example, the XY table (not depicted) of the wafer supply unit 10, the ZY drive shaft of a bond head table, and the drive unit of the pushup unit 13. The I/O signal control device 83f acquires or controls signals from the signal unit 87 that includes, for example, various sensors and switches and variable resistors for controlling the brightness of lighting devices. The optical system 88 includes the wafer recognition camera 14, the stage recognition camera 34, and the substrate recognition camera 44. The control processing device 81 acquires necessary data through the bus line 84, performs calculations, controls, for example, the pickup head 21, and sends information, for example, to the monitor 83a.

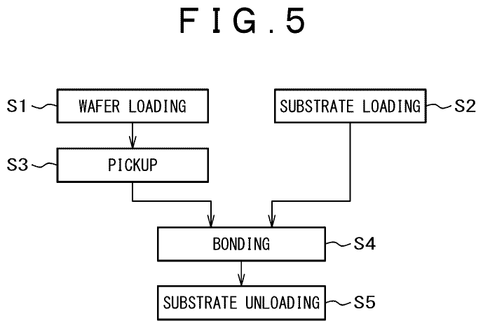

A part of a method for manufacturing semiconductor device (method for manufacturing semiconductor device) by using the die bonder 1 will now be described with reference to FIG. 5. FIG. 5 is a flowchart illustrating a method for manufacturing the semiconductor device by using the die bonder depicted in FIG. 1. Operations of individual sections of the die bonder 1, which are described below, are controlled by the control unit 80.

### Wafer Loading Process (Step S1)

The wafer rings WR are supplied to the wafer cassette of the wafer cassette lifter 11. The supplied wafer rings WR are then forwarded to the wafer holding table 12.

### Substrate Loading Process (Step S2)

The carrying jig storing the substrate S is supplied to the substrate supply unit 60. In the substrate supply unit 60, the substrate S is removed from the carrying jig, and fastened to the carrying claws 51.

### Pick-Up Process (Step S3)

After completion of step S1, the wafer holding table 12 is moved so that a desired die D can be picked up from the dicing tape DT. The wafer recognition camera 14 captures an image of the die D, and then the die D is subjected to positioning and surface inspection based on image data acquired by image capturing. Image processing is performed on the image data in order to calculate the amount of deviation (in the X, Y, and θ directions) of the die D on the wafer holding table 12 from a die position reference point of the die bonder and perform positioning. It should be noted that a predetermined position of the wafer holding table 12 is stored in advance as an initial apparatus setting indicating the die position reference point. The surface inspection of the die D is conducted by performing image processing on the image data.

The positioned die D is peeled off from the dicing tape DT by the pushup unit 13 and the pickup head 21. The die D peeled off from the dicing tape DT is adsorbed and held by the collet 22 disposed on the pickup head 21, and carried to and placed on the intermediate stage 31.

The stage recognition camera 34 captures an image of the die D on the intermediate stage 31, and then the die D is subjected to positioning and surface inspection based on image data acquired by image capturing. Image processing is performed on the image data in order to calculate the amount of deviation (in the X, Y, and θ directions) of the die D on the intermediate stage 31 from a die position reference point of the die bonder and perform positioning. It should be noted that a predetermined position of the intermediate stage 31 is stored in advance as an initial apparatus setting indicating the die position reference point. The surface inspection of the die D is conducted by performing image processing on the image data.

The pickup head 21, which has carried the die D to the intermediate stage, is returned to the wafer supply unit 10. The above-described procedure is followed to peel off the next die D from the dicing tape DT. Subsequently, the dies D are peeled off one by one from the dicing tape DT by following the procedure similar to the above.

### Bonding Process (Step S4)

The substrate S is carried to the bond stage 46 by the carrier unit 50. An image of the substrate S placed on the bond stage 46 is captured by the substrate recognition camera 44, and then the substrate S is subjected to positioning and surface inspection based on image data acquired by image capturing. An image processing is performed on the image data in order to calculate the amount of deviation (in the X, Y, and θ directions) of the substrate S from a substrate position reference point of the die bonder 1. It should be noted that a predetermined position of the bonding unit 40 is stored in advance as an initial apparatus setting indicating the substrate position reference point. The surface inspection of the substrate S is conducted by performing image processing on the image data.

An adsorption position of the bond head 41 is corrected based on the amount of deviation of the die D on the intermediate stage 31, which has been calculated in step S3, and then the die D is adsorbed by the collet 42. The bond head 41, which has adsorbed the die D from the intermediate stage 31, bonds the die D to a predetermined location on the substrate S supported by the bond stage 46. In this instance, the predetermined location of the substrate S is a package area P of the substrate S, or an area where an element is already placed and another element is to be bonded in addition to that, or a bonding area for an element to be bonded in stack form. An image of the die D bonded to the substrate S is captured by the substrate recognition camera 44, and then inspection is performed, for example, to determine whether the die D has been bonded at a desired position based on the image data acquired by image capturing.

The bond head 41, which has bonded the die D to the substrate S, is returned to the intermediate stage 31. The above-described procedure is followed to pick up the next die D from the intermediate stage 31 and bond the next die D to the substrate S. The above is repeated to bond the dies D to all the package areas P of the substrate S.

### Substrate Unloading Process (Step S5)

The substrate S, to which the dies D are bonded, is carried to the substrate unloading unit 70. In the substrate unloading unit 70, the substrate S is removed from the carrying claws 51 and stored in the carrying jig. The carrying jig storing the substrate S is unloaded from the die bonder 1.

As described above, the dies D are mounted on the substrate S and unloaded from the die bonder 1. Subsequently, for example, the carrying jig storing the substrate S, on which the dies D are mounted, is carried to a wire bonding process, and then electrodes of the dies D are electrically connected to electrodes of the substrate S, for example, via Au wires. The substrate S is then carried to a molding process, where the die D and the Au wires are sealed with a mold resin (not depicted) to complete a semiconductor package.

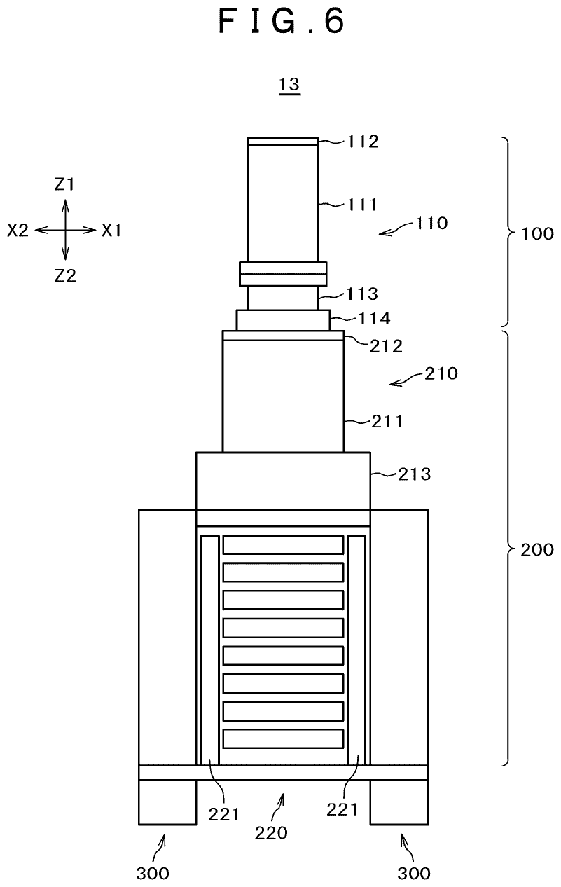

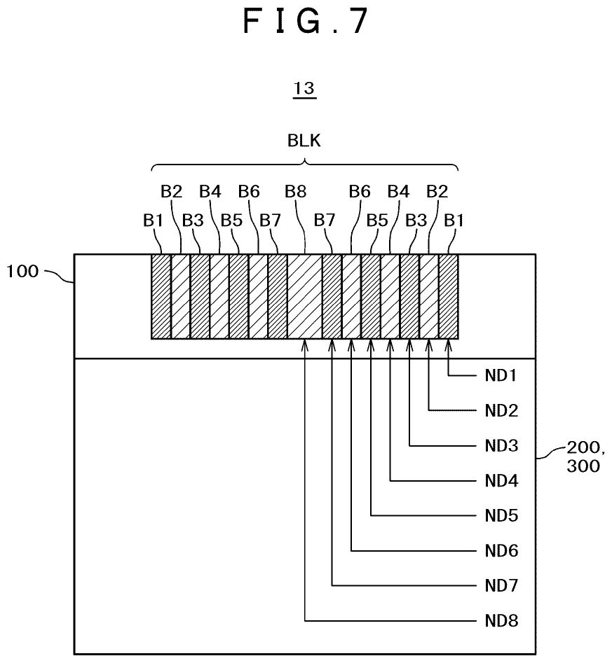

The pushup unit 13 will now be outlined with reference to FIGS. 6 and 7. FIG. 6 is a front view of a pushup unit in the embodiment. FIG. 7 is a schematic diagram illustrating the pushup unit depicted in FIG. 6.

As depicted in FIG. 6, the pushup unit 13 includes a head section 100, a mechanism section 200, and a drive section 300. As depicted in FIG. 7, the head section 100 includes a pushup block section BLK that has a plurality of blocks B1 to B8. The mechanism section 200 drives the blocks B1 to B8 in the vertical direction. The mechanism section 200 includes an upper plate section 210 and a lower block section 220. The upper plate section 210 acts as a first mechanism section or a second mechanism section. The lower block section 220 acts as the first mechanism section or the second mechanism section. The drive section 300 generates a vertical motion, and transmits the vertical motion to the lower block section 220. The lower block section 220 transmits the vertical motion, which is generated by the drive section 300, to the upper plate section 210. The upper plate section 210 transmits a vertical motion generated by the lower block section 220 to the head section 100.

The mechanism section 200 may be formed by the upper plate section 210 and the drive section 300. In this case, the drive section 300 generates a vertical motion, and transmits the vertical motion to the upper plate section 210. The upper plate section 210 transmits a vertical motion generated by the drive section 300 to the head section 100. The mechanism section 200 may be formed by the lower block section 220 and the drive section 300. In such an instance, the drive section 300 generates a vertical motion, and transmits the vertical motion to the lower block section 220. The lower block section 220 transmits a vertical motion generated by the drive section 300 to the head section 100.

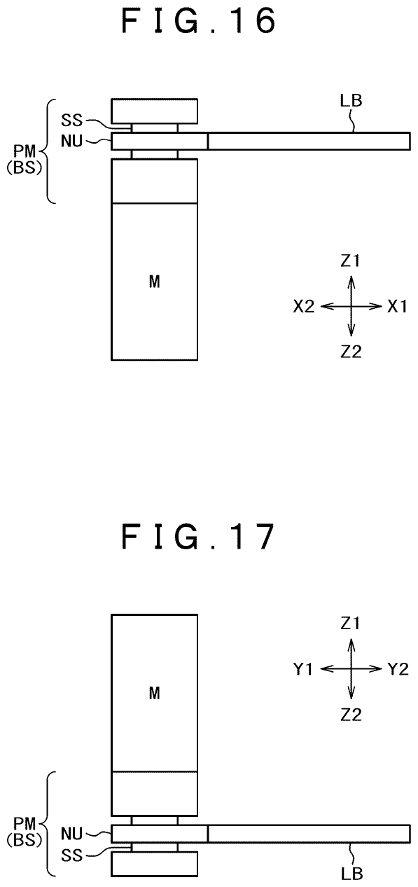

As depicted in FIG. 7, the blocks B1 to B8 can be independently moved up and down by the mechanism section 200 and by drive shafts ND1 to ND8 of the drive section 300. Each of the drive shafts ND1 to ND8 is formed by a later-described motor M (see FIG. 16) and plunger mechanism in order to vertically move the blocks B1 to B8. The plunger mechanism includes the upper plate section 210, the lower block section 220, and the drive section 300 excluding the motor M.

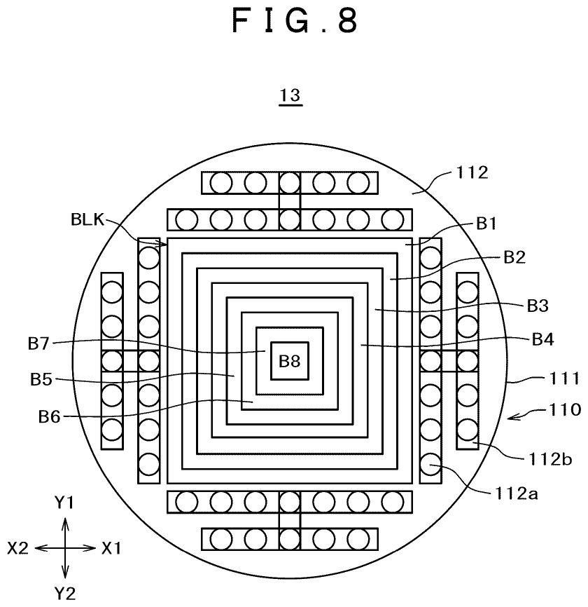

The head section 100 will be described with reference to FIGS. 6 and 8. FIG. 8 is a top view of a head section depicted in FIG. 6.

As depicted in FIG. 8, the head section 100 includes a dome 110 and the pushup block section BLK, which is disposed in the dome 110. The dome 110 includes a cylindrical member 111, a disk-shaped member 112, and another cylindrical member 113. The cylindrical members 111, 113 are disposed on the upper end of the cylindrical member 111. An opening is provided in the center of the disk-shaped member 112 so that the pushup block section BLK is able to move up and down through this opening. The periphery of the disk-shaped member 112 is provided with a plurality of suction ports 112a and a plurality of grooves 112b. The plurality of grooves 112b connect the plurality of suction ports 112a. The inside of the suction ports 112a is depressurized by a suction mechanism (not depicted) when the pushup unit 13 is to be raised to bring its upper surface into contact with the back surface of the dicing tape DT. In this instance, the back surface of the dicing tape DT is sucked downward and brought into close contact with the upper surface of the dome 110 (disk-shaped member 112). As depicted in FIG. 6, an annular member 114 is disposed on the outside of the cylindrical member 113. The dome 110 is fastened to the upper plate section 210 by the annular member 114.

The blocks B1 to B8 of the pushup block section BLK push the dicing tape DT upward. The seven outer blocks B1 to B7 have a hollow columnar shape (e.g., a square cylindrical shape), and are provided with openings that penetrate in the Z1-22 direction and have the same shape as the outer shape of an internally positioned block. The innermost block B8 has a solid columnar shape (e.g., a square columnar shape). The block B2 is placed inside the block B1, which is the largest in size, the block B3 is placed inside the block B2, and the block B4 is placed inside the block B3. The block B5 is placed inside the block B4, the block B6 is placed inside the block B5, the block B7 is placed inside the block B6, and the block B8, which is the smallest in size, is placed further inside.

It is preferable that the outermost block B1, which is the largest in size among the eight blocks B1 to B8, be slightly smaller in size than the outer circumference of the die D to be peeled off. As a result, the corners of the upper surface of the block B1 are positioned slightly inside the outer edge of the die D. Consequently, the force for peeling the die D and the dicing tape DT from each other can be concentrated at a point (the outermost periphery of the die D) that serves as the starting point for peeling the two apart. Here, the outer periphery of the die D protruding outward from the end of the outermost block B1 is called an overhang (OH).

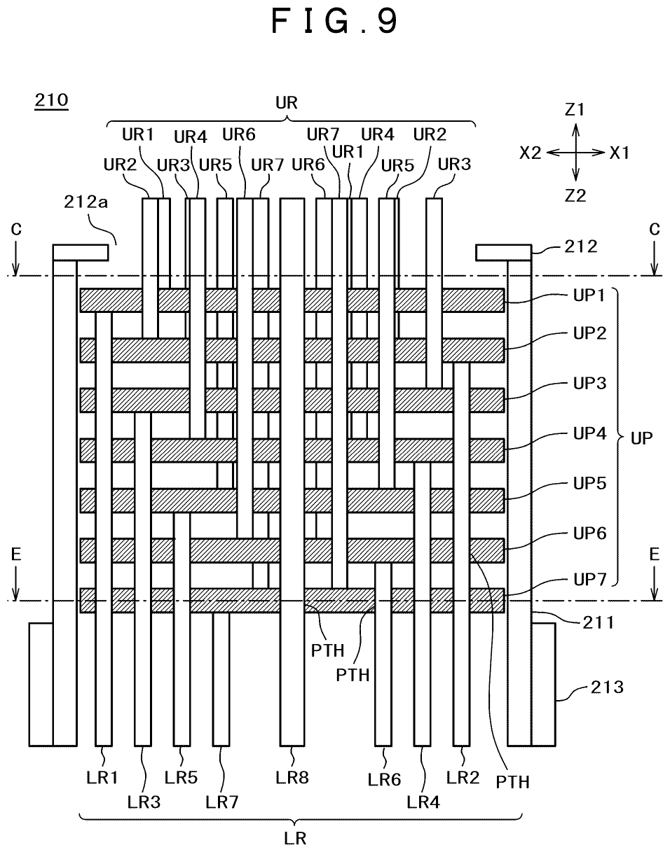

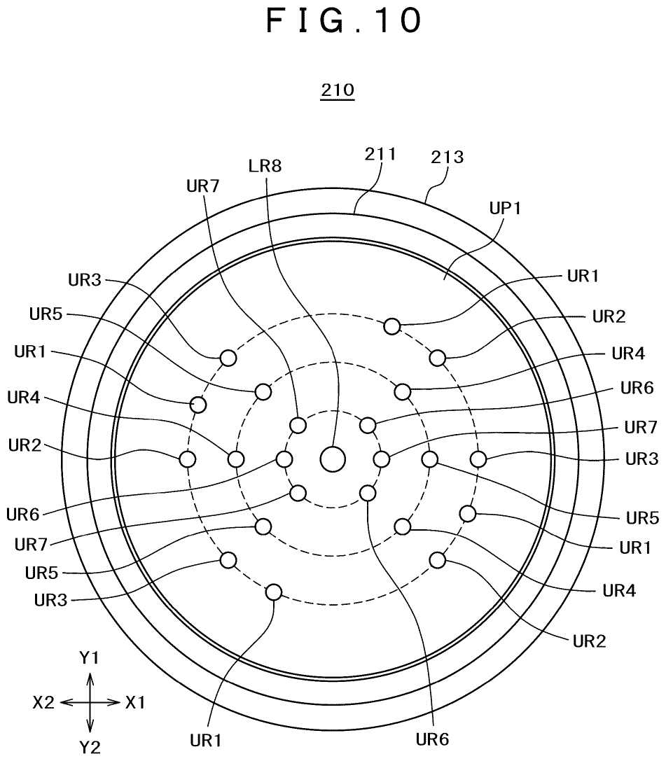

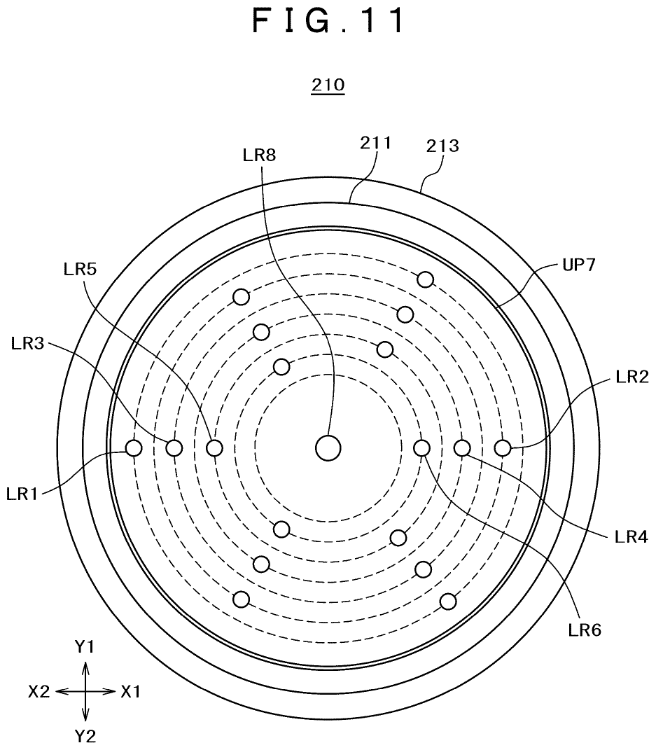

The upper plate section 210 of the mechanism section 200 will now be described with reference to FIGS. 9 to 11. FIG. 9 is a longitudinal cross-sectional view of an upper plate section depicted in FIG. 6. FIG. 10 is a transverse cross-sectional view of the upper plate section taken along line C-C in FIG. 9. FIG. 11 is a transverse cross-sectional view of the upper plate section taken along line E-E in FIG. 9.

As depicted in FIG. 9, the upper plate section 210 includes an upper rod UR, an upper plate UP, and a dome. The dome covers the upper rod UR and the upper plate UP. The dome is formed by a cylindrical member 211 and a disk-shaped member 212. The disk-shaped member 212 is disposed on the upper end of the cylindrical member 211. An annular member 213 is disposed on the outside of the cylindrical member 211. The cylindrical member 211 is fastened to the lower block section 220 by the annular member 213. An opening 212a is provided in the center of the disk-shaped member 212 so that the upper rod UR is able to move up and down through this opening 212a. The upper rod UR includes rods UR1 to UR7. The upper plate UP includes plates UP1 to UP7. The each of the rods UR1 to UR7 is referred to as a first rod, a second rod or a third rod.

Each of the rods UR1 to UR7 is disposed on the upper surface side of the corresponding one of the plates UP1 to UP7, and extended in the Z direction. The rods UR1 to UR7 are fastened at one end to the plates UP1 to UP7 and at the other end to the blocks B1 to B7. It is preferable that the outermost block B1 use the top plate UP1. As a result, the outer block B1, which has a large outer shape and needs to be rigid, can be pushed up by the rod UR1, which is the shortest, highly rigid pin and used as a plunger.

As depicted in FIG. 10, four pieces of the rod UR1 are provided, and three pieces each of the rods UR2 to UR7 are provided. This allows the block B1 to be supported at four points, and each of the blocks B2 to B7 to be supported at three points, thereby providing increased rigidity between the block section BLK and the upper plate UP and providing increased parallelism during ascent and descent. Three or more of each of the rods UR1 to UR7 may be provided. It is preferable that a plurality of rods forming the rod UR1 be arranged concentrically at equal intervals. It is preferable that a plurality of rods forming each of the rods UR2 to UR7 be also arranged concentrically at equal intervals. This increases the parallelism of the blocks B1 to B7 during ascent and descent. The rods UR1 to UR7 transmit the vertical motions of the plates UP1 to UP7 to the blocks B1 to B7.

Additionally, the mechanism section 200 has a rod LR8 that passes through the upper plate section 210. The rod LR8 is fastened at one end to a block LB8 of a later-described lower block LB and at the other end to the block B8 of the block section BLK. Only one piece of the rod LR8 is provided. It is preferable that the rod LR8 be larger in diameter than the rods UR1 to UR7.

The plates UP1 to UP7 are arranged at predetermined intervals in the vertical direction (Z direction). The plates UP1 to UP7 are disk-shaped members. Further, the plates UP1 to UP7 have operational clearance from the inner wall of the dome (cylindrical member 211). The above-described configuration makes it possible to dispose many rods and maintain their parallel and vertical orientation during operation. The number of pieces of the upper plate UP is one less than the number of blocks in the block section BLK. Alternatively, however, they may be the same (eight). However, when the innermost block B8 is pushed up by the rod LR8 on an as-is basis (without using a plate), the mechanism can be simplified because the parallelism of the innermost block B8 can be easily maintained due to its small outer shape.

The plates UP1 to UP6 have through-holes PTH through which the rods UR2 to UR7 pass. The rods UR2 to UR7 are to be connected to the plates UP2 to UP7, which are positioned below the plates UP2 to UP7, respectively. Further, the plates UP2 to UP7 have through-holes PTH through which rods LR1 to LR6 pass. The rods LR1 to LR6 are to be connected to later-described blocks LB1 to LB7, which are used for connecting, respectively, to the upper plates UP1 to UP6 positioned above. Then, the plates UP1 to UP7 have through-holes PTH through which the rod LR8 passes. It is preferable that the through-holes PTH and the rods UR2 to UR7, LR8 have the same shape when viewed from above. Clearance is provided to allow driving. It should be noted that the through-holes PTH and the rods UR2 to UR7, LR8 do not necessarily have the same shape. This allows the dome to accommodate a link mechanism that transmits many driving forces from the lower block section 220 to the pushup block section BLK.

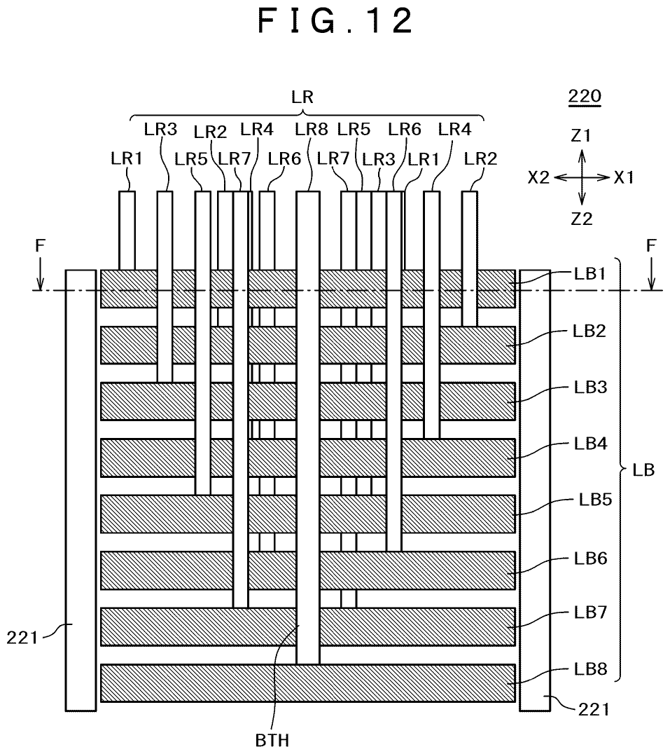

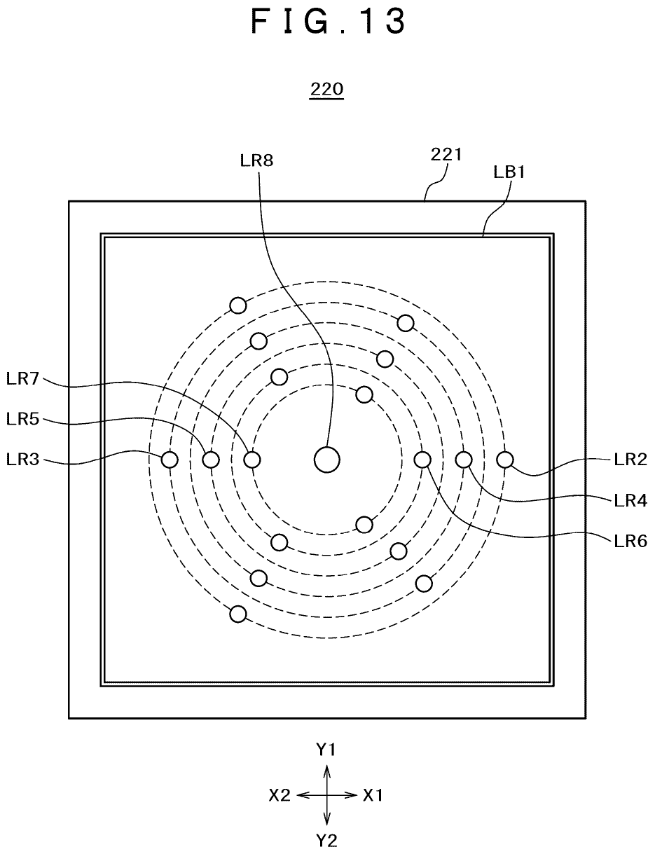

The lower block section 220 of the mechanism section 200 will be described with reference to FIG. 6, 12 or 13. FIG. 12 is a longitudinal cross-sectional view of a lower block section depicted in FIG. 6. FIG. 13 is a transverse cross-sectional view of the lower block section taken along line F-F in FIG. 12.

As depicted in FIG. 12, the lower block section 220 includes a lower rod LR, a lower block LB, and a housing that covers the lower rod LR and the lower block LB. The housing is formed by members 221 that are provided on a back section and both side sections. The lower rod LR includes the rods LR1 to LR8. The lower block LB includes the block LB1 to LB8. The each of the rods LR1 to LR8 is referred to as a first rod, a second rod or a third rod.

Each of the rods LR1 to LR8 is disposed on the upper surface side of the corresponding one of the blocks LB1 to LB8, and extended in the Z direction. The rods LR1 to LR8 are fastened at one end to the blocks LB1 to LB8 and at the other end to the plates UP1 to UP7. The other end of the rod LR8 is fixed to the block B8.

As depicted in FIG. 13, three pieces each of the rods LR1 to LR7 are provided. This allows each of the blocks B1 to B7 to be supported at three points, thereby providing increased rigidity between the upper plate UP and the lower block LB and providing increased parallelism during ascent and descent. Four or more of each of the rods LR1 to LR7 may be provided. It is preferable that a plurality of rods forming the rod LR1 be arranged concentrically at equal intervals. It is preferable that a plurality of rods forming each of the rods LR2 to LR7 be arranged concentrically at equal intervals. Further, it is preferable that a plurality of rods forming the rod LR1 be arranged at equal angular intervals. It is preferable that a plurality of rods forming each of the rods LR2 to LR7 be arranged at equal angular intervals. This increases the parallelism of the blocks B1 to B7 during ascent and descent. The rods LR1 to LR7 transmit the vertical motions of the blocks LB1 to LB7 to the plates UP1 to UP7. The rod LR8 transmits the vertical motions of the block LB8 to UP7 to the block B8.

The blocks LB1 to LB8 are arranged in the vertical direction. The blocks LB1 to LB8 are circular, rectangular, or polygonal members. The blocks LB1 to LB8 are formed to be thicker than the plates UP1 to UP7. The blocks LB1 to LB7 have through-holes BTH through which the rods LR2 to LR8 pass. The rods LR2 to LR8 are to be connected to the blocks LB2 to LB8, which are positioned below the blocks LB1 to LB7, respectively. It is preferable that the through-holes BTH and the rods LR2 to LR8 have the same shape when viewed from above. Clearance is provided to allow driving on an independent basis. It should be noted that the through-holes PTH and the rods UR2 to UR7, LR8 do not necessarily have the same shape.

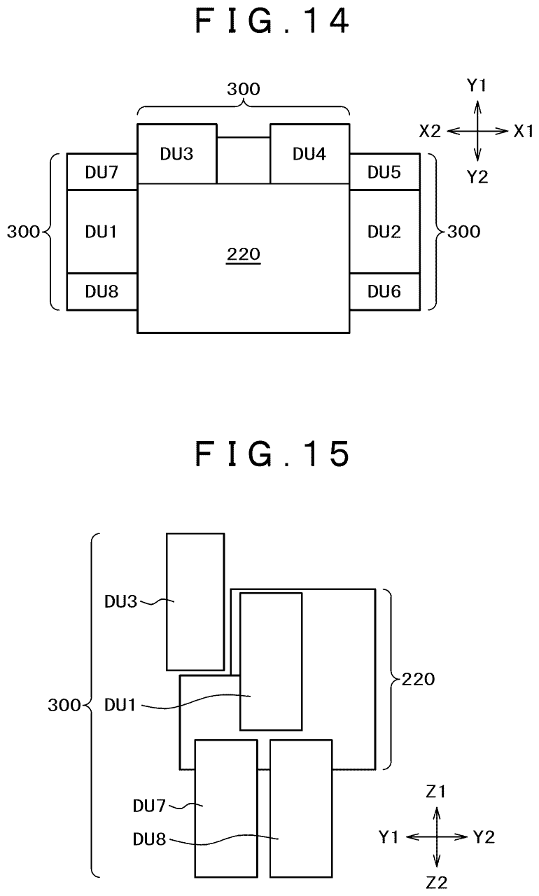

The drive section 300 will be described with reference to FIGS. 14 to 17. FIG. 14 is a top view illustrating an example of layout of the drive section depicted in FIG. 6. FIG. 15 is a side view illustrating an example layout of the drive section depicted in FIG. 6. FIG. 16 is a diagram illustrating an example of the configuration of the drive section depicted in FIG. 15. FIG. 17 is a diagram illustrating another example of the configuration of the drive section depicted in FIG. 15.

The drive section 300 includes drive sections DU1 to DU8. The drive sections DU1 to DU8 are arranged around the lower block section 220 and fastened to the members 221. The drive sections DU1, DU7, DU8 are disposed on the X2 side of the lower block section 220. The drive sections DU2, DU5, DU6 are disposed on the X1 side of the lower block section 220. The drive sections DU3 and DU4 are disposed on the Y1 side of the lower block section 220. The drive sections DU1 and DU2 are disposed on the upper side of the lower block section 220. The drive sections DU5 to DU8 are disposed on the lower side of the lower block section 220.

The drive sections DU1 to DU8 respectively drive the blocks LB1 to LB8 in the vertical direction. Each of the drive sections DU1 to DU8 includes a motor M and a drive output section PM. The drive output section PM converts the rotation of the motor M into a vertical motion.

The drive output section PM includes a ball screw BS. The ball screw BS is formed by a screw shaft SS, which is connected to the motor M, and a nut section NU, which is threadedly engaged with the screw shaft SS. The nut section NU is screwed or otherwise fastened to the lower block LB. The motor M is disposed so as to extend its output shaft in the vertical direction. That is to say, the screw shaft SS of the ball screw BS is disposed so as to extend in the vertical direction.

The motor M may be disposed with its output shaft (motor shaft) facing upward as depicted in FIG. 16, or may be disposed with its output shaft facing downward as depicted in FIG. 17. That is to say, the drive output section PM may be disposed above the motor M, or may be disposed below the motor M. The motors M of the drive sections DU1, DU2, DU5 to DU8 are disposed as depicted in FIG. 16. The motors M of the drive sections DU3, DU4 are disposed as depicted in FIG. 17. This allows the motor M to be compactly accommodated, and provides flexibility in arrangement.

Further, the lower block section 220 receives the thrust of the drive output section PM by using the side surface or upper or lower surface of the lower block LB, and transmits motive power to the lower rod LR. This provides improved flexibility in arrangement of the drive output section PM and of a motive power source (motors M) in a case where many motive power sources (motors M) are provided.

The present embodiment provides at least one of the following advantageous effects (a) to (g).
(a) It is possible to increase the number of blocks in the pushup block section BLK.
(b) Since the peel area per block (block width) can be reduced due to advantageous effect (a), it is possible to reduce the stress on the dies during die peeling.
(c) Even in a case where the dies are increased in size, the overhang can be reduced due to advantageous effect (a).
(d) Since the outer periphery of a die can be peeled off at a low pushup height to position an outermost peripheral pushup block lower than a total pushup height due to advantageous effect (c), it is possible to reduce the deformation of surrounding dies. This shortens the distance between the end face of the outermost peripheral pushup block and the end face of a pickup die. As a result, the surrounding dies are less likely to deform.
(e) Product defects can be reduced due to advantageous effect (d).
(f) Thin dies can be processed in a stable manner due to advantageous effect (d).
(g) Since the upper plate section 210 includes a disk-shaped member and a rod, it is possible to suppress an increase in a dome diameter even if the number of blocks in the pushup block section BLK is increased. This makes it possible to maintain compatibility with the pushup unit having a smaller number of blocks. This will be explained below.

As described above, the wafer holding table 12 is moved in the X and Y directions by the XY table so that the die D to be picked up is moved to the position of the pushup unit 13. However, in a case where the die D to be picked up is in the vicinity of the wafer rings WR, the pushup unit 13 is positioned near the members of the wafer holding table 12, such as the support ring 122 and the XY table. If the dome 110 of the pushup unit 13 and the dome of the upper plate section 210 are increased in size, these members of the wafer holding table 12 become an obstacle. As a result, the die D to be picked up is unable to move to the position of the pushup unit 13. That is to say, the area on the wafer that permits die pickup (pickup area) is reduced. Consequently, in a case where the configuration of the wafer holding table 12 remains unchanged, the pushup unit 13 cannot be made larger in size than a predetermined value. It should be noted that, if the number of blocks is large in a case where a second unit 13b in Japanese Unexamined Patent Application Publication No. 2017-224640 includes a plurality of circular tubular blocks, the diameter of the second unit 13b increases due to machining accuracy.

The present disclosure made by the present inventors has been specifically described above based on an embodiment. However, it is obvious that the present disclosure is not limited to the foregoing embodiment and can be variously modified.

For example, the foregoing embodiment has been described with reference to an example in which the pushup block section BLK includes eight blocks B1 to B8. However, the number of blocks included in the pushup block section BLK may be larger or smaller than eight. The number of blocks in the pushup block section BLK should be two or more.

In a case where the number of blocks in the pushup block section BLK is not eight, the configurations of the head section 100 and mechanism section 200 are to be changed. The numbers of upper plates, lower blocks, and motors are to be changed in accordance with the number of blocks. For example, in a case where the pushup block section BLK includes two blocks, one upper plate, two lower blocks, and two motors are to be provided.

In a case where the number of blocks in the pushup block section BLK is smaller than eight, only the configuration of the head section 100 is to be changed, and the configuration of the mechanism section 200 need not be changed. In this case, there is an upper rod that is not connected to the block section BLK; however, the motor for moving such the upper rod is to remain inoperative.

The foregoing embodiment has been described with reference to an example in which clearance is provided between the through-hole BTH in the lower block LB and the lower rod LR so that they can be driven independently. However, for example, a bearing may alternatively be provided to permit independent driving. When the above alternative is adopted, the plunger (rod) for transmitting motive power between the plates (surfaces) is kept perpendicular and can be operated with high precision.

The foregoing embodiment has been described with reference to an example in which the upper plate UP is disk-shaped. However, the upper plate UP may alternatively be shaped like a polygon so that the inner surface of the dome comes into contact with a plurality of (three or more) points or faces. Further, bearings or pulleys may be provided on the sides of the polygon. Adopting the above alternative makes it possible to maintain the parallelism of a plurality of upper plates UP.

The foregoing embodiment has been described with reference to an example in which the die attach film is used. However, an alternative is to provide a preform unit for applying an adhesive to the substrate without using the die attach film.

The die bonder described in conjunction with the foregoing embodiment is configured such that the pickup head picks up the dies from the wafer supply unit, places the dies on the intermediate stage, and allows a bonding head to bond the dies placed on the intermediate stage to the substrate. However, the present disclosure is not limited to the above-mentioned configuration. The present disclosure can also be applied to a die bonding device that picks up dies from a die supply unit.

For example, the present disclosure is also applicable to a die bonder that has neither an intermediate stage nor a pickup head and allows the bonding head to bond the dies in the wafer supply unit to the substrate.

Further, the present disclosure is also applicable to a flip chip bonder that does not have an intermediate stage, picks up a die from a wafer supply unit, rotates a die pickup head upward to deliver the die to a bonding head, and allows the bonding head to bond the dies to a substrate.

In the foregoing embodiment, a die bonder has been described as an example. However, the present disclosure is also applicable to a semiconductor manufacturing apparatus that places picked-up dies on a tray.

What is claimed is:

1. A semiconductor manufacturing apparatus comprising:
a pushup unit that includes a head section having a plurality of blocks, a mechanism section for moving each of the plurality of blocks up and down on an independent basis, and a drive section that includes a motor and a drive output section for converting the motive power of the motor to a vertical motion; and
a head that has a collet adsorbing a die,
wherein the mechanism section includes a first mechanism section having
a first member that has an upper surface, a lower surface opposite the upper surface, and a through-hole penetrating between the upper surface and the lower surface,
a first rod that is connected to the upper surface of the first member to convey the vertical motion of the first member to the blocks, and
a second rod that is extended from below through the through-hole to convey the vertical motion to the blocks.

2. The semiconductor manufacturing apparatus according to claim 1,
wherein the mechanism section further includes a second mechanism section having
a third rod that is connected to the lower surface of the first member, and
a second member that has an upper surface, a lower surface opposite the upper surface, and a through-hole penetrating between the upper surface and the lower surface, and is configured to connect the third rod to the upper surface.

3. The semiconductor manufacturing apparatus according to claim 1,
wherein the mechanism section further includes a second mechanism section having
a second member that has an upper surface, a lower surface opposite the upper surface, and a through-hole penetrating between the upper surface and the lower surface, and is configured to connect the first rod to the lower surface, and
a third rod that is connected to the upper surface of the second member.

4. The semiconductor manufacturing apparatus according to claim 2,
wherein a plurality of pieces of the first member of the first mechanism section are arranged in the vertical direction;
wherein a plurality of pieces of the second member of the second mechanism section are arranged in the vertical direction;
wherein the drive section has a plurality of pieces of the motor and a plurality of pieces of the drive output section; and
wherein the number of the first members of the first mechanism section is equal to or smaller than the number of the second members of the second mechanism section.

5. The semiconductor manufacturing apparatus according to claim 2,
wherein a plurality of pieces of the first member of the first mechanism section are arranged in the vertical direction;
wherein a plurality of pieces of the second member of the second mechanism section are arranged in the vertical direction;
wherein the drive section has a plurality of pieces of the motor and a plurality of pieces of the drive output section;
wherein the number of the first members of the first mechanism section is equal to or smaller than the number of the blocks;
wherein the number of the second members of the second mechanism section is equal to the number of the drive output sections; and
wherein the number of the drive output sections is equal to the number of the motors.

6. The semiconductor manufacturing apparatus according to claim 4,
wherein at least three pieces of the first rods are disposed on the upper surface of each of the plurality of the first members of the first mechanism section;
wherein, one piece of the second rod is disposed on the upper surface of one piece of the plurality of second members of the second mechanism section; and
wherein at least three pieces of the third rod are disposed on the upper surface of each of the plurality of the other second members of the second mechanism section.

7. The semiconductor manufacturing apparatus according to claim 5,
wherein at least three pieces of the first rods are disposed on the upper surface of each of the plurality of the first members of the first mechanism section;
wherein, one piece of the second rod is disposed on the upper surface of one piece of the plurality of second members of the second mechanism section; and
wherein at least three pieces of the third rod are disposed on the upper surface of each of the plurality of the other second members of the second mechanism section.

8. The semiconductor manufacturing apparatus according to claim 6,
wherein the first rods are arranged concentrically at equal intervals; and
wherein the third rods are arranged concentrically at equal intervals.

9. The semiconductor manufacturing apparatus according to claim 4,
wherein the first mechanism section is accommodated in a cylindrical housing; and
wherein the first members of the first mechanism section are circular or polygonal in shape when viewed from above, and clearance is provided to allow driving between the first members and the inside diameter of the housing.

10. The semiconductor manufacturing apparatus according to claim 5,
wherein the first mechanism section is accommodated in a cylindrical housing; and
wherein the first members of the first mechanism section are circular or polygonal in shape when viewed from above, and clearance is provided to allow driving between the first members and the inside diameter of the housing.

11. The semiconductor manufacturing apparatus according to claim 2,
wherein the second members of the second mechanism section are circular, rectangular, or polygonal in shape when viewed from above.

12. The semiconductor manufacturing apparatus according to claim 4,
wherein the outer ones of the plurality of the blocks are pushed up by the first rods disposed on the upper ones of the plurality of the first members of the first mechanism section.

13. The semiconductor manufacturing apparatus according to claim 5,
wherein the outer ones of the plurality of the blocks are pushed up by the first rods disposed on the upper ones of the plurality of the first members of the first mechanism section.

14. The semiconductor manufacturing apparatus according to claim 4,
wherein the second rod is configured to push up the innermost one of the plurality of the blocks without being connected to the plurality of the first members of the first mechanism section.

15. The semiconductor manufacturing apparatus according to claim 5,
wherein the second rod is configured to push up the innermost one of the plurality of the blocks without being connected to the plurality of the first members of the first mechanism section.

16. The semiconductor manufacturing apparatus according to claim 5,
wherein each of the plurality of the drive output sections is fastened to the plurality of the second members of the second mechanism section.

17. The semiconductor manufacturing apparatus according to claim 12,
wherein the drive section is disposed around, above, or below the second mechanism section.

18. The semiconductor manufacturing apparatus according to claim 13,
wherein the plurality of the motor shafts of the motors are oriented upward or downward.

19. A pushup unit comprising:
a head section having a plurality of blocks, a mechanism section for moving each of a plurality of blocks up and down on an independent basis, a motor, and a drive section having a drive output section for converting the motive power of the motor to a vertical motion,
wherein the mechanism section includes a first mechanism section having
a member that has an upper surface, a lower surface opposite the upper surface, and a through-hole penetrating between the upper surface and the lower surface,
a first rod that is connected to the upper surface of the member to convey the vertical motion of the member to the blocks, and
a second rod that is extended from below through the through-hole to convey the vertical motion to the blocks.

20. A method for manufacturing semiconductor device, comprising the steps of:
loading a wafer ring holding a dicing tape into the semiconductor manufacturing apparatus according to claims 1; and
picking up a die attached to the dicing tape.
